(19) United States
(12) Patent Application Publication
(10) Pub. No.: US 2007/0263367 A1
(43) Pub. Date: Nov. 15, 2007

(54) Electronic subassembly, electronic assembly, and method for producing an electronic assembly

(75) Inventors: Harald Fischer, Braubach/Rhein (DE); Martin Motz, Heilbronn (DE); Dieter Mutz, Heilbronn (DE)

Correspondence Address: MCGRATH, GEISSLER, OLDS & RICHARDSON, PLLC, P.O. BOX 1364, FAIRFAX, VA, 22038-1364, US

(73) Assignee: ATMEL Germany GmbH

(21) Appl. No.: 11/723,314

(22) Filed: Mar. 19, 2007

(30) Foreign Application Priority Data
Mar. 18, 2006 (DE) DE102006012 600.9

(51) Int. Cl. H05K 5/00

(52) U.S. Cl. 361/752

(57) ABSTRACT

An electronic subassembly is provided that includes at least one integrated circuit which is housed in a dimensionally stable plastic package and which is connected in an electrically conductive manner to at least one externally accessible, electrically conductive contact prong on the plastic package. An electronic assembly is also provided with such an electronic subassembly, and a method for producing an electronic assembly. According to the invention, provision is made for at least one recess to be provided in the plastic package, designed in particular as an indentation, in which at least one contact prong is arranged such that it is exposed.

This nonprovisional application claims priority under 35 U.S.C. § 119(a) on German Patent Application No. DE 102006012600, which was filed in Germany on Mar. 18, 2006, and which is herein incorporated by reference.

### BACKGROUND OF THE INVENTION

1. Field of the Invention

The present invention relates to an electronic subassembly having at least one integrated circuit which is housed in a dimensionally stable plastic package and which is connected in an electrically conductive manner to at least one externally accessible, electrically conductive contact prong on the plastic package. The invention also relates to an electronic assembly based on the electronic subassembly, and a method for producing an electronic assembly.

2. Description of the Background Art

Electronic subassemblies with various methods of construction are known from the prior art. The invention relates primarily to electronic subassemblies with a construction such as is described in DE 103 10 260 A1 by the applicant, for example. In this type of electronic subassemblies, an integrated circuit is provided in the form of a semiconductor chip, which is connected to a contact body through bond wires. The bond wires create an electrically conductive connection to the electrically conductive contact body. The contact body has at least one external contact area that is provided for contacting a surface, for example a circuit board designed as a printed circuit (PCB—printed circuit board). The integrated circuit, the bond wires, and the contact body are encapsulated in a protective material, typically an epoxy resin, in order to minimize environmental influences on the integrated circuit and the bonded connections. Such a subassembly can be defined in accordance with the standards JEDEC JC-11, MO-220 four side, MO-2209 two side (connection sides), and is called a quad flat non-lead component. Other package shapes and constructions for electronic subassemblies are also encompassed by the invention.

### SUMMARY OF THE INVENTION

It is an object of the present invention to provide an electronic subassembly, an electronic assembly, and a method for producing electronic assemblies that provide more flexibility in application and increased functional reliability.

This object is attained according to a first aspect of the invention through an electronic subassembly in which there is provided on the plastic package at least one recess, designed in particular as an indentation, in which at least one contact prong is arranged such that it is exposed. An electronic component, in particular a sensor element, can be placed in the indentation and connected in an electrically conductive manner through the at least one contact prong to the integrated circuit accommodated in the electronic subassembly. For an electrical connection to the at least one contact prong, the electronic component has at least one, preferably metallic, contact area that can be connected to the contact prong by means of one of the contact methods named below. No additional unit such as a circuit board need be employed for the electrical and mechanical coupling of the electronic component to the electronic subassembly. Instead, the electronic component is placed directly in the indentation and is electrically contacted. The recess is preferably matched to the size of the electronic component and permits an essentially complete accommodation of the electronic component, so that the latter preferably terminates flush with an outer surface of the electronic subassembly.

The establishment of an electrical connection between the electronic component and the at least one contact prong projecting into the recess can, in particular, be implemented by soldering, bonding, conductive adhesive, laser soldering, or laser welding. This direct connection of the electronic component to the integrated circuit accomplishes an advantageous electrical connection that is distinguished from a coupling using an interposed circuit board by significantly reduced transition resistances and stray capacitances. When a circuit board is used for coupling the electronic component to the electronic subassembly, each electrical connection should be routed through the circuit board, so that a contact point with the circuit board can be realized in each case from the electronic component as well as from the electronic subassembly. In order to connect the contact points, copper conductive traces can be used in the circuit board. Since each contact point entails a risk of a faulty electrical connection, and the copper traces in the circuit board can be faulty or incorrectly wired, the inventive, direct coupling of the electronic component to the contact prongs of the electronic subassembly produces a significant improvement in functional reliability of an electronic assembly distinguished thereby. In addition, the electronic assembly encompassing the electronic component and electronic subassembly can be produced more economically because of the smaller number of electrical connections to be produced and because of the omission of a circuit board.

In an embodiment of the invention, provision is made for at least one exposed contact prong to be provided on at least one outer surface of the plastic package distant from the recess, the contact prong being designed, for example, for an electrically conductive surface mounting. By means of the at least one contact prong distant from the recess, and hence not intended for direct electrical connection of an electronic component, the electronic subassembly can, if placed on a circuit board, be electrically connected to a contact surface of the circuit board. This makes it possible, for example, to supply the electronic subassembly with electric voltage and/or to route electrical signals to and/or from a control and/or analysis unit coupled to the circuit board. As a result, the electronic subassembly can be integrated into an electronic circuit arrangement in a known way, such as is known for control units in the automotive field, in particular.

Another embodiment of the invention provides that exposed contact prongs are arranged only in the recess of the plastic package. In this embodiment of the invention, the electronic subassembly is not provided for electrical connection to a circuit board, but instead is standalone in design, and is preferably designed to be driven in a contactless manner. The electronic subassembly can be supplied with electric power either by a voltage supply integrated in the electronic subassembly, or by coupling in an external energy field, for example an electric field. Routing of electrical signals to and/or from the electronic subassembly likewise takes place in a contactless manner, for example by changing the incident electric field or by active transmission of a signal by the electronic subassembly. In this way, an electronic assembly made up of the electronic subassembly and an electronic component can be used with particular flexibility even in places where a wired energy supply and a wired routing of electrical signals in and/or out would be complicated or impossible.

Another embodiment of the invention provides that the recess is designed at least in sections as a cutout or notch wherein at least one contact prong provided in the recess is arranged to project from the plastic package. This makes it possible to achieve an especially flexible attachment of an electronic component in the recess. A cutout in the plastic package of the electronic subassembly makes it possible to attach the electronic component from a top or from a bottom side of the electronic subassembly. If the cutout and contact prong are designed appropriately, it is also possible to attach electronic components on both sides of the electronic subassembly. In a notch, which is to say a recess designed as a niche in an end face of the plastic package, it is possible to attach an electronic component that is designed as, for example, a sensor element and has an active sensor area on more than one outer surface.

Another embodiment of the invention provides that the recess is designed as a cutout, and the at least one contact prong is designed as a free-standing post or as a bridge-like post, wherein the plastic package encloses the recess, in particular in the manner of a frame. As a result, attachment of the electronic component can be carried out from two opposite sides of the plastic package. Electrical contact of the electronic component to the contact prongs designed as free-standing or bridge-like posts facilitates an especially advantageous design of the electrical connections. A contact prong designed as a free-standing post is attached to the plastic package on one side and projects into the cutout. A contact prong of bridge-like design is accommodated in the plastic package at each of two opposite end regions, permitting a stable connection between the plastic package and the electronic component that is capable of transmitting forces.

According to another aspect of the invention, an electronic assembly is provided which has an electronic subassembly and at least one electronic component, wherein the at least one electronic component is electrically coupled to the at least one contact prong provided in the recess and is encapsulated with a molding compound that at least partially surrounds the electronic component. The molding compound ensures an advantageous mechanical, and in some circumstances also thermal and/or electrical, connection between the plastic package and electronic component. The molding compound also prevents environmental influences, such as moisture for example, from affecting the electrical connections between the electronic component and the contact prongs.

In another embodiment of the invention, provision is made for the recess to be designed as a positive-locking coupling structure, which is provided for correct positioning of the electronic component that is designed to correspond, at least in sections, to the coupling structure and that can be electrically connected to the at least one contact prong. In this way, a simple and reliable orientation of the electronic component relative to the plastic package can be achieved. In an embodiment of the invention, the recess is provided, at least in sections, with an undercut, in particular in the manner of a dovetail guide. This permits the implementation of a mechanical coding between the recess and electronic component, in which the electronic component can only be installed in the recess in exactly one definable, precisely reproducible position.

In another embodiment of the invention, provision is made for the molding compound to be selected such that the electronic component is embedded in the recess essentially free of internal mechanical stresses. Consequently, the electronic component, which can be a sensor for determining a measured quantity, is not adversely affected by the molding compound with respect to its measurement accuracy, even when an electromechanical measurement principle is used, as in the case of a deformation sensor such as a strain gauge, in particular. As a result, the provision of exact measured values is influenced only negligibly by the mechanical properties of the molding compound, in particular its temperature-dependent expansion.

In another embodiment of the invention, provision is made for the molding compound to be a silicone gel, which in the cured state has a Shore hardness matched to the electronic component of less than 60, especially preferably less than 40, in particular less than 30, and thus has a Shore hardness matched to the sensor type or actuator type. Preferred is a Shore hardness (Shore A, 20 degrees Celsius) of less than 60, especially preferably less than 40, in particular less than 30. In this way, it is ensured that internal mechanical stresses induced by the molding compound are significantly smaller than the internal stresses that occur in any case in the package of the electronic component, and hence do not result in undesirable changes in the properties of the electronic component.

In another embodiment of the invention, provision is made for the electronic component to be a pressure sensor, in particular for measuring a fluid or gas pressure. The electronic component can thus be used as, for example, a pressure sensor for a tire pressure measurement system (TPMS).

In another embodiment of the invention, provision is made for another electronic component in the form of a motion sensor and/or acceleration sensor to be associated with the pressure sensor. With a motion and/or acceleration sensor, preferably attached in the same recess or in another recess of the electronic subassembly, a result measured by the pressure sensor can be brought into correlation with the motion of the tire in which the tire pressure measurement system is installed. Preferably the motion sensor is capable of detecting a rotational direction of the tire. In the event of pressure loss in the tire during travel, the pressure sensor can thus generate a warning message that is transmitted to a control unit or directly to a display device.

In another embodiment of the invention, provision is made for the integrated circuit or the electronic component to be designed as an RFID unit and/or as a signal processor and/or as a memory unit. With an RFID unit, contactless signal transmission, in particular of measured data from a sensor, can be achieved. Preferably a signal processor is associated with the sensor, permitting processing, in particular digitizing, of the measured values. A memory unit permits the temporary, volatile, or nonvolatile storage of measured values.

According to another aspect of the invention, provision is made for a method for producing an electronic assembly with the following steps: producing at least one electrical connection between an integrated circuit and at least one contact prong, in particular through bonding; encasing the integrated circuit, the electrical connections, and the contact prong with a hardenable molding compound to form a dimensionally stable plastic package in a mold, wherein the molding process leaves open a recess in the plastic package in which is arranged at least one exposed contact prong. Using this method, an electronic subassembly is produced that is ready for the installation of one or more electronic components capable of directly contacting the contact prongs. In this context, multiple contact prongs may be combined to form a contact body, also known as a lead frame. The lead frame has a circumferential frame to which the contact prongs are attached and which is separated in a later step in order to achieve contact prongs that are electrically isolated from one another. The integrated circuit, especially implemented as a silicon die, typically has a ground area on one underside, and is provided on an upper side with bond pads, permitting a material-to-material attachment of aluminum or gold bond wires, which are connected to the contact prongs. The molding compound which is used to create the plastic package embeds the integrated circuit, the electrical connections, and also the contact prongs in some areas, in a material-to-material way, thus achieving encapsulation from environmental influences.

In another embodiment of the invention, the following additional steps are provided: insertion of at least one electronic component in the recess of the electronic subassembly; production of an electrically conductive connection between the electronic component and at least one exposed contact prong located in the recess; embedding the at least one electronic component in the recess with a hardenable, in particular low-stress hardening, molding compound. By means of one of the aforementioned contacting methods, the electronic component is electrically connected to the integrated circuit by the shortest path possible for two discrete, separately implemented subassemblies. More direct coupling of the subassemblies is only possible if the two subassemblies are directly connected to one another, such as can typically be achieved in multi-chip modules. However, such multi-chip modules do not by any means have the flexibility of application that can be achieved with an electrical component and a discrete electronic component that is attachable thereto.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a perspective top view of a first embodiment of an electronic assembly;

FIG. 2 is a perspective view from below of the electronic assembly;

FIG. 3 is a plane top view of the electronic assembly;

FIG. 4 is a plane side view of the electronic assembly;

FIG. 5 is a plane view from below of the electronic assembly;

FIG. 6 is a perspective drawing of a second embodiment of an electronic subassembly,

FIG. 7 is a perspective drawing of an electronic component adapted for the electronic subassembly from FIG. 6.

### DETAILED DESCRIPTION

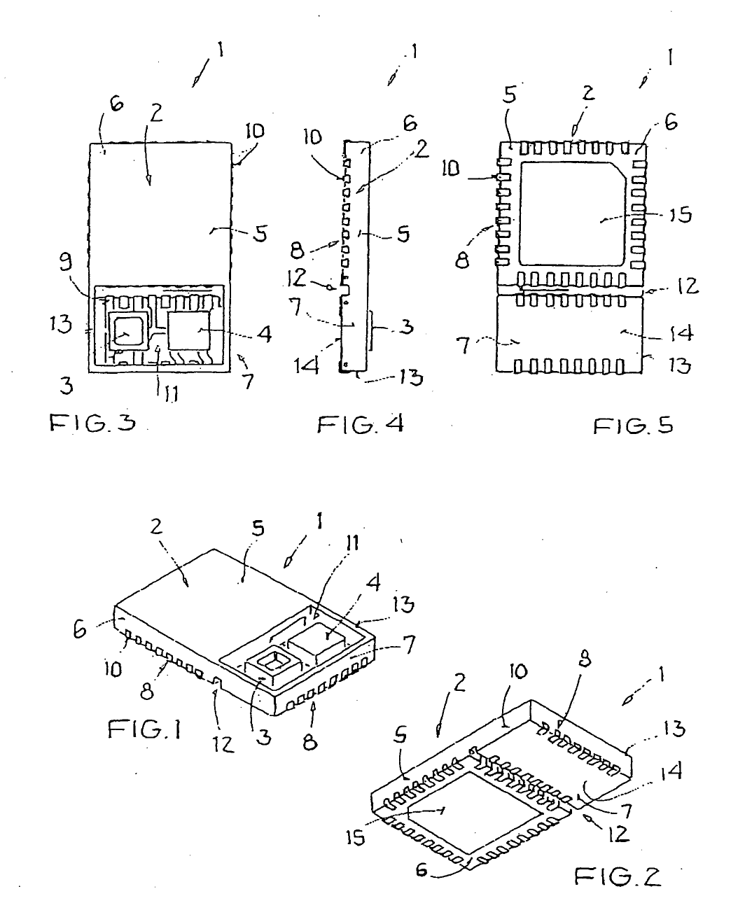

FIGS. 1 through 5 show an electronic assembly 1, which is composed of an electronic subassembly 2 and two electronic components 3, 4. The electronic assembly 1 is housed in a dimensionally stable plastic package 5, which by way of example is composed of a QFN package 6 of type QFN_{—}5×8_{—}32L and an expansion region 7 secured thereto as a single piece. The digits indicate that the QFN package has an edge length of 5 mm by 8 mm and is equipped with 32 contacts.

The purpose of the expansion region 7 is to accommodate the two discrete electronic components 3, 4, which are shown in detail in FIGS. 1 and 3. Contained in the QFN package 6, but not shown, is an integrated circuit, which is connected in an electrically conductive fashion to electrically conductive contact prongs, externally accessible on the plastic package 5. A relatively large number of contact prongs is designed as solder pads 8 on a circumferential edge region 10 of the QFN package 6 and of the expansion region 7, and is intended for surface mounting of the plastic package 5 on a circuit board (not shown). Face-centered on the underside of the QFN package 6 there is provided a thermally conductive area 15 that ensures conduction of heat from the integrated circuit to an environment or preferably to a thermally coupled circuit board that is not shown. Provided between the QFN package 6 and the expansion region 7 is a separating groove 12, which ensures reliable soldering of the solder pads 8 of the QFN package 6 and those of the expansion region 7 located opposite thereto and a short distance away, without undesirable solder bridges arising between the opposing solder pads 8 during the soldering process as a result of capillary action or other effects.

Some of the contact prongs project into a recess 11 in the form of an indentation, which is shaft-like and rectangular in design, provided in the expansion region 7. The recess 11 occupies a substantial volume of the expansion region 7 and extends to the QFN package 6. The expansion region 7 thus comprises a circumferential edge 13 and a bottom region 14, which closes off the recess 11 at the base and serves as a support surface for the contact prongs designed as contact areas 9. The contact areas 9 permit surface mounting of the electronic components 3, 4 by known contacting methods such as soldering, conductive adhesive bonding, or laser soldering. The contact areas 9 rest on the bottom region 14, and are thus supported in advantageous fashion. The electronic components 3, 4 are implemented as a pressure sensor and as an acceleration sensor, thus permitting dynamic measurement of a tire pressure in a motor vehicle, for example. The integrated circuit is designed as a signal processor with a memory unit and RFID unit, and permits the processing, storage, and contactless transmission of the measured signals from the pressure sensor and acceleration sensor. Accommodation of the electronic components 3, 4 in the recess 11 makes it possible to ensure flexibility in the manufacturing processes for the electronic assembly 1, as different pressure sensors, in particular for different pressures, must be used for different tires, for example. However, all pressure sensors require signal processing, storage, and transmission to be connected after them; this can be implemented in the integrated circuit. As a result, identical electronic subassemblies 2 with identical integrated circuits can be produced in a first step, which then in a subsequent step are populated with the pressure and acceleration sensors appropriate for the particular requirement, thus producing electronic assemblies 1 with different properties. Once the electronic components 3, 4 have established contact with the contact surfaces 9, they are encapsulated with a molding compound (not shown), which preferably is chosen in the form of a two component system having a binder and a hardener, and thus can cure without external influences such as increased temperature or ultraviolet radiation. The molding compound is preferably also selected such that it has low internal stresses and high flexibility, in order to avoid the exertion of mechanical stresses on the electronic components 3 and 4 during temperature fluctuations.

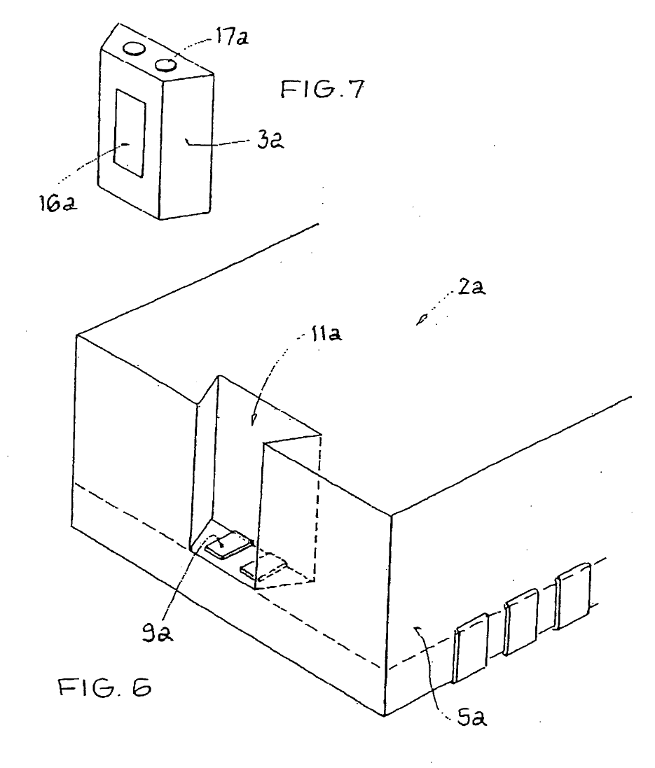

In the electronic subassembly 2a shown in FIG. 6, the recess 11a in the plastic package 5a takes the form of a positive-locking coupling structure, which is designed for correct positioning of the electronic component 3a. On the electronic component 3a, which is implemented as a pressure sensor with an end-face sensor surface 16a, are provided—on an upper side as shown in FIG. 7—two contact fields 17a, which are intended for electrical contact with the contact surfaces 9a located in the recess 11a. Due to the dovetail-shaped contour of the recess 11a, the electronic component 3a can only be mounted in the correct position on the electronic subassembly 2a, thus making possible a reliable manufacturing process.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An electronic subassembly comprising:
at least one integrated circuit which is housed in a dimensionally stable plastic package and which is connected in an electrically conductive manner to at least one externally accessible electrically conductive contact prong on the plastic package; and
at least one recess being provided on the plastic package, the at least one recess being an indentation in which at least one contact prong is arranged such that it is exposed.

2. The electronic subassembly according to claim 1, wherein at least one exposed contact prong is provided on at least one outer surface of the plastic package distant from the recess, the exposed contact prong being provided for facilitating an electrically conductive surface mounting.

3. The electronic subassembly according to claim 1, wherein exposed contact prongs are arranged only in the recess of the plastic package.

4. The electronic subassembly according to claim 1, wherein the recess is designed at least in sections as a cutout or notch, and wherein at least one contact prong provided in the recess is arranged to project from the plastic package.

5. The electronic subassembly according to claim 1, wherein the recess is designed as a cutout or notch, and the at least one contact prong is designed as a free-standing post or as a bridge-like post, and wherein the plastic package encloses the recess, in particular in the manner of a frame.

6. An electronic assembly comprising an electronic subassembly according to claim 1, and comprising at least one electronic component, wherein the at least one electronic component is electrically coupled to the at least one contact prong provided in the recess and is encapsulated with a molding compound that at least partially surrounds the electronic component.

7. The electronic assembly according to claim 6, wherein the recess is designed as a positive-locking coupling structure, which is provided for correct positioning of the electronic component that is designed to correspond, at least in sections, to the coupling structure and that can be electrically connected to the at least one contact prong.

8. The electronic assembly according to claim 7, wherein the molding compound is selected such that the electronic component is embedded in the recess essentially free of internal mechanical stresses.

9. The electronic assembly according to claim 8, wherein the molding compound is a silicone gel, which in a cured state has a Shore hardness matched to the electronic component of less than 60, especially preferably less than 40, in particular less than 30.

10. The electronic assembly according to claim 6, wherein the electronic component is a pressure sensor for measuring a gas pressure.

11. The electronic assembly according to claim 10, wherein another electronic component in the form of a motion sensor and/or acceleration sensor is associated with the pressure sensor.

12. The electronic assembly according to claim 6, wherein the integrated circuit or the electronic component is an RFID unit and/or a signal processor and/or a memory unit.

13. A method for producing an electronic assembly, the method comprising:
producing at least one electrical connection between an integrated circuit and at least one contact prong through bonding; and
encasing the integrated circuit, the electrical connections, and the contact prong with a hardenable molding compound to form a dimensionally stable plastic package in a mold,
wherein the molding process leaves open a recess in the plastic package in which is arranged at least one exposed contact prong.

14. The method for producing an electronic assembly according to claim 13, further comprising:
inserting at least one electronic component in the recess of the electronic subassembly;
producing an electrically conductive connection between the electronic component and at least one exposed contact prong located in the recess; and
embedding the at least one electronic component in the recess with a hardenable low-stress hardening molding compound.
